(19) United States
(12) Patent Application Publication
(10) Pub. No.: US 2008/0007991 A1
(43) Pub. Date: Jan. 10, 2008

(54) Reversed Magnetic Tunneling Junction for Power Efficient Byte Writing of Mram

(76) Inventors: Anthonie Meindert Herman Diteweg, Eindhoven (NL); Roger Cuppens, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(21) Appl. No.: 11/597,881

(22) PCT Filed: May 18, 2005
(86) PCT No.: PCT/IB05/51618

§ 371 Date: Nov. 27, 2006

(30) Foreign Application Priority Data
May 27, 2004 (EP) 04102362.3

(51) Int. Cl. G11C 11/16; H01L 21/00

(52) U.S. Cl. 365/158; 438/3; 257/E21.001

(57) ABSTRACT

A magnetoresistive memory device comprises magnetoresistive cells, each cell comprising a free magnetic layer and a fixed magnetic layer. The device furthermore comprises a bit line for each magnetoresistive cell and digit lines. Each digit line is common to a number of magnetoresistive cells and is positioned in a direction perpendicular to the bitlines. The magnetic layers are positioned in between the bitlines and the digit lines, but in a reversal of the usual layout according to the prior art, i.e. the digit line is positioned closer to the fixed magnetic layer than to the free magnetic layer. This enables a reduction in total write current where the write current in the line nearer the magnetic layer can be less than the current in a line spaced further away. Since there are more bit lines than digit lines activated, the total of the bit currents and the digit current can be reduced. Reduced total write current is useful in mobile battery powered applications to maximize battery life.

### FIELD OF THE INVENTION

This invention relates to magnetoresistive devices, to integrated circuits having such devices, and to methods of manufacturing and methods of writing and/or reading such devices.

### DESCRIPTION OF THE RELATED ART

Magnetoresistive random access memories (MRAMs) are one known type of non-volatile memory devices. An MRAM comprises a plurality of magnetic memory cells exploiting a magnetoresistive effect which appears in multi-layer films that have alternately stacked magnetic layers and non-magnetic layers. Magnetic resistance over a magnetic memory cell indicates minimum or maximum values according to whether magnetic vectors in magnetic layers point in the same or in opposite directions, respectively. The same and opposite directions of magnetic vectors in two magnetic layers are called “Parallel” and “Antiparallel” states, respectively. When magnetic material is employed for a memory device, parallel and antiparallel directions, for example, are logically defined as “0” and “1” states, respectively.

An example of part of a known MRAM showing an array of integrated memory cells is shown in perspective view in FIG. 1. This structure and how to manufacture it is well known and need not be described again in detail here. To summarise, such MRAM contains cells with magnetic tunnel junctions (MTJs). MTJs basically contain a free magnetic layer 100, an insulating layer (tunnel barrier 102), a pinned magnetic layer 104, and an antiferromagnetic AF layer 106 which is used to “pin” the magnetization of the pinned layer to a fixed direction. In the example shown in this figure, there is also an underlayer 108. For simplicity, only 4 active layers are shown in the magnetic tunnel junction (MTJ) stack shown in FIG. 1. In practice there may be more layers, which are not relevant to the principle of operation.

The MRAM cells store information (1/0) in the directions of magnetization of the free magnetic layer, which can be relatively free to rotate between two opposite directions. The resistance of the MTJ is small if the directions of the free layer is parallel with that of the pinned layer and is large when this direction is opposed. For reading information on a certain cell, a small voltage is applied over the MTJ stack (vertically) of the selected cell. The measured current through the MTJ (proportional to the resistance) is the indication of the information of the cell. The information on a cell can be changed during a write operation by sending write currents through word lines WL1-3 and bit lines BL1-3, which are patterned at the bottom and on top of the memory cells. The currents will create magnetic fields (easy axis field and hard axis field) in the memory cell. The fields are programmed so that they are large enough to switch the magnetization of the free layer of the selected cell (at the crossing of the word line and bit line) to the direction determined by the current direction in the bit line. The bit lines are parallel with the hard axis of the cells, which creates a field in the easy axis, while the digit or word lines otherwise create a field in the hard axis.

Bit lines and word lines are shown as being perpendicular, with magnetic tunnel junctions placed at the intersections. The inset shows hard axis field (created by word line) and easy axis field (created by a current direction in the bit line). The resultant field is directed at 45° with respect to the easy axis, which is able to rotate, if needed, the magnetization of the free layer of the selected cell, while all unselected cells are not affected. The bottom electrodes of the cells are connected to the selection transistors with vias, which are used for cell selection when reading.

As the resultant field makes an angle of 45° with respect to the easy axis of the free layer of the cell, the switching field of the free layer is the smallest, thus writing can be done with the least current. The magnitude of resultant magnetic field at the crossing point is (|H_{HA}|+|H_{EA}|)/−√2, in which H_{HA} and H_{EA} are the fields created in the hard axis and easy axis, respectively. They must generally have the same magnitude. For more information on such MRAMs, the reader is referred to for example P. K. Naji, M. Durlam, S Tehrani, J. Calder and M. F. DeHerrera, “A 256 kb 3.0V 1 TIMTJ nonvolatile magnetoresistive RAM”, IEEE Int. Solid-State Circuits Conference 2001, section 7.6. and R. Scheuerlein, W. Gallagher, S. Parkin, A. Lee, S. Ray, R. Robertazzi, W. Reohr, “A 10 ns Read and Write nonvolatile memory array using a magnetic tunnel junction and FET switch in each cell”, IEEE Int. Solid-State Circuits Conference 2000, section TA 7.2.

Another known MTJ cell is shown in FIG. 2. In this case a write bit line 10 is laid over a parallel local interconnect line 20. The magnetic layers of the cell are below these lines. The free magnetic layer 30 is above an AlOx barrier layer 40, which is in turn above the fixed magnetic layer 50. Below these layers is a Ru layer 60 followed by a pinned layer 70 and an AF layer 80. Next is a base electrode 90, and a digit line 95 on top of a substrate (not shown). The base electrode is connected to ground through an isolation transistor. Other parts of the memory chip such as other memory cells, addressing and timing circuitry, and read and write circuits are not shown for the sake of brevity. Likewise the read and write operation of these devices can follow known practice and need not be described here in more detail.

Another example is shown in U.S. Pat. No. 5,946,227. It shows a MRAM device having magnetic memory cells on intersections of word and bit lines, which are placed in rows and columns respectively. Activation of word and bit lines enables the MRAM device to select the memory cell for reading or writing. In this case the bit line is directly coupled to the memory cells and a sense current flows in the magnetic layers so that the sense current is affected by magnetic vectors in the magnetic layers and the sense current value in the memory cell or the voltage drop across the memory cell is dependent on the direction of magnetic vectors. On the other hand, a writing process is carried out by applying a sufficient magnetic field to switch magnetic vectors in the magnetic layers. In order to meet the magnetic requirements, a torque or digit line is placed in parallel with the word line to provide a digit current. The digit, word, and sense currents all create a total magnetic field and apply it to the memory cell, which stores states in accordance with directions of the total magnetic field. To overcome increased resistance in the word line, if it is made from poly silicon, connections between the word line and the parallel digit line are made. The reduced resistance can lead to faster access times.

Another device is known from US patent application 2002/0131295. The mentioned problems with current architecture include high programming currents, insufficient space on the substrate, and efficient timing of memory cycles during read and program cycles. The method of US 2002/0131295 proposes a single digit line current source shared between two arrays of memory cells. This can save space on the substrate. Timing signals of a clocking system enable prevention of current flow into word/digit lines that are in the process of being deselected.

However, there still remains a need for magnetoresistive devices with lower power consumption.

### SUMMARY OF THE INVENTION

An object of the invention is to provide improved devices, methods of operation and methods of manufacture.

According to a first aspect, the invention provides a magnetoresistive device comprising a number of magnetoresistive cells logically organized in rows and columns, each cell comprising a free magnetic layer and a fixed magnetic layer. The device furthermore comprises a bit line for each column of magnetoresistive cells and digit lines, each digit line being common to a number of magnetoresistive cells in a row and being positioned perpendicular to the bit lines. The distance between a digit line and the pinned or fixed magnetic layer of a magnetoresistive cell is called a first distance, the distance between the digit line and the free magnetic layer of the same cell is called a second distance. In an aspect of the device of the present invention, the first distance is smaller than the second distance. In other words, the magnetic layers are arranged adjacent to their respective bit line and adjacent to the digit line and such that the bit line is closer than the digit line to the free magnetic layer. In this invention, the digit line and bit line are referred to in their functional sense independent of their physical position with respect to the magnetic layers.

The construction of the device according to the present invention is reversed with respect to the conventional relative locations of the magnetic layers according to the prior art. In the device according to the invention, the line on top of the magnetoresistive element is the digit line and the write line between the magnetoresistive element and the substrate the bit line. The present invention exploits the insight that the amount of write current in the line nearer to the magnetic layer can be less than the amount of current in a line at larger distance. Since during write in a memory there are more bit lines than digit lines activated, the total of the bit line currents and the digit line current for changing the state of the cells can be reduced if the bit lines are arranged as set out above. This can be achieved here by reversing the relative location of the two current carrying lines and reversing the order of the magnetic layers. Reducing the overall write current is particularly useful to enable more bits to be integrated onto single chips, or can enable faster devices. It is particularly useful for use in mobile battery powered applications to maximize battery life.

In one embodiment, the device may be a memory device for storing bits in magnetoresistive memory cells. The memory device may for example be an MRAM device comprising MRAM cells for storing bits. This is currently the most valuable application of such magnetoresistive devices. However, also other applications are known and can gain some benefit from the invention. Writing such elements takes considerable current, and can limit the performance of such devices, hence it is valuable to be able to reduce such writing current.

In another embodiment, the free magnetic layer and/or the fixed magnetic layer may be positioned in between the digit line and the bit line. This is a common arrangement for efficient operation, however, other arrangements may be conceivable and may gain some benefit from the invention.

In one embodiment, the magnetoresistive device may furthermore comprise a local interconnect line parallel to and adjacent to each of the bit lines and, according to this invention, on the opposite side of the magnetic layers as the bit line. This local interconnect line may also carry the write current or part of the write current in the bit line (current flow in opposite direction) and so there is potential for more reduction in overall write current In another aspect of the invention, the magnetoresistive cells each comprise an MTJ cell. Effectively, the order of layers in the MTJ cell may be reversed to benefit from the above mentioned advantages. The MTJ cell may furthermore comprise a pinned magnetic layer, and an antiferromagnetic AF layer in between the digit line and the fixed magnetic layer. These are some of the principal layers of such cells. The advantages may also apply to other types of cells. The layers may form for example a stack alternatingly comprising magnetic and non-magnetic layers.

In yet another embodiment, the bit line may be located between a substrate of the device and the bit stores, the digit lines being located above the bit stores that are the magnetoresistive cells. In particular, the bit line may be located between a substrate and a base electrode, the base electrode being positioned at a first side of the device while the digit lines may be located at a second side of the device, the first and second side of the device being opposite to each other.

The digit line may for example be coupled to eight or more magnetoresistive cells. This is a common configuration to enable a byte of 8 bits to be addressed and read or written. In this case, to program a byte, 8 times the write-bit line current is needed and 1 times the digit line current.

Another aspect of the invention provides an integrated circuit comprising an embedded MRAM. The MRAM may comprise one or more of the devices according to the present invention.

Another aspect of the invention provides a method for manufacturing a magnetoresistive device comprising a number of magnetoresistive cells, each cell comprising a free magnetic layer and a fixed magnetic layer. The device furthermore comprises a bit line for each column of magnetoresistive cells and digit lines, each digit line being common to a number of magnetoresistive cells in a row and being positioned in a direction perpendicular to the bit lines. The distance between the digit line and the fixed or pinned magnetic layer of a magnetoresistive cell is smaller than the distance between the digit line and the free magnetic layer of the same magnetoresistive cell. The method comprises

forming a bit line onto a substrate,

forming a free magnetic layer on top of said bit line,

forming a barrier layer on top of said free magnetic layer,

forming a fixed magnetic layer on top of said barrier layer, and

forming a digit line on top of said fixed magnetic layer.

In one embodiment, the method may furthermore comprise forming a pinned magnetic layer and an antiferromagnetic layer in between the fixed magnetic layer and the digit line.

The invention furthermore provides a method for writing a group of bits to a group of cells of a magnetoresistive memory device, each cell comprising a free magnetic layer and a fixed magnetic layer. The device furthermore comprises a bit line for each magnetoresistive cell and digit lines, each digit line being common to each cell of said group of cells and being positioned in a direction perpendicular to the bitlines. The distance between the digit line of a magnetoresistive cell and its fixed magnetic layer is smaller than the distance between the digit line and the free magnetic layer of the same magnetoresistive cell. The method comprises:

applying a bit writing current to the bit lines of at least one cell, and

applying a digit write current to the digit line.

Any of the additional features can be combined with each other and with any aspect of the invention. Other advantages will be apparent to those skilled in the art, particularly in view of other prior art not yet known to the inventors. How the present invention may be put into effect will now be described with reference to the appended schematic drawings. Obviously, numerous variations and modifications can be made without departing from the spirit of the present invention. Therefore, it should be clearly understood that the form of the present invention is illustrative only and is not intended to limit the scope of the present invention.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIGS. 1 and 2 show known arrangements,

FIG. 3 shows in schematic form an embodiment of the invention,

FIG. 4 shows another embodiment, and

FIG. 5 shows a schematic view of a group of bit lines and a digit line.

In the different figures, the same reference signs refer to the same or analogous elements.

### DESCRIPTION OF THE PREFERRED EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

Throughout this description, the terms “column” and “row” are used to describe sets of array elements which are linked together. The linking can be in the form of a Cartesian array of rows and columns however the present invention is not limited thereto. As will be understood by those skilled in the art, columns and rows can be easily interchanged and it is intended in this disclosure that these terms be interchangeable. Also, non-Cartesian arrays may be constructed and are included within the scope of the invention. Accordingly the terms “row” and “column” should be interpreted widely. To facilitate in this wide interpretation, the claims refer to logically organised rows and columns. By this is meant that sets of memory elements are linked together in a topologically linear intersecting manner however, that the physical or topographical arrangement need not be so. For example, the rows may be circles and the columns radii of these circles and the circles and radii are described in this invention as “logically organised” rows and columns. Also, specific names of the various lines, e.g. bitline, wordline or digit line are intended to be generic names used to facilitate the explanation and to refer to a particular function, and this specific choice of words is not intended to in any way limit the invention. It should be understood that all these terms are used only to facilitate a better understanding of the specific structure being described, and are in no way intended to limit the invention.

### FIGS. 3, 5 a First Embodiment of the Invention

FIG. 3 schematically shows some of the principal parts of a magnetoresistive device according to a first embodiment of the present invention. The device described in this embodiment may, for example, be part of a memory device or other device.

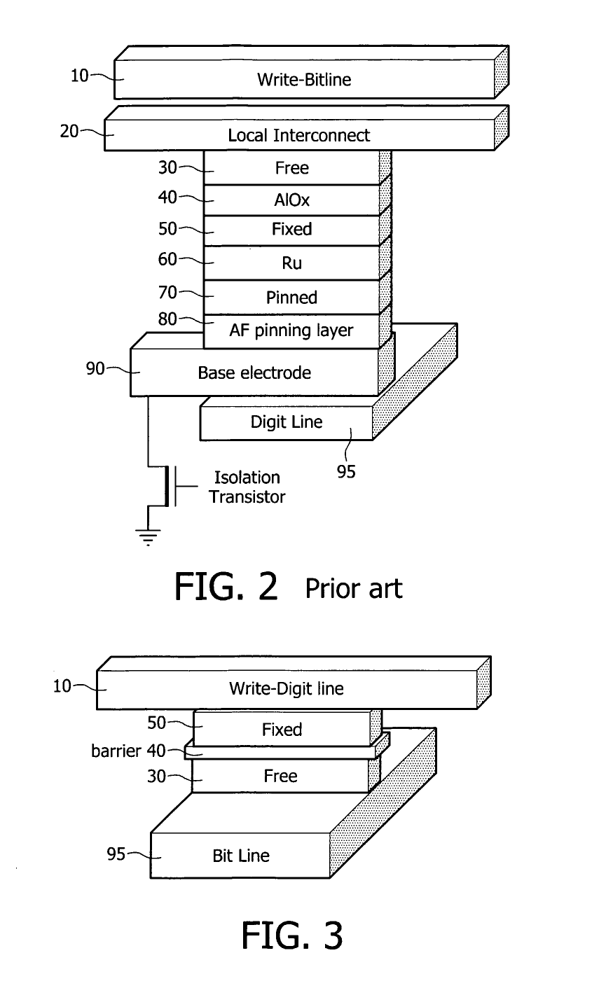

The device comprises a free magnetic layer 30, a fixed magnetic layer 50 and a barrier layer 140 in between the two magnetic layers 30, 50. In this embodiment, a write-digit line 10 is provided on top of the magnetic layers 30, 50 of the cell (FIG. 3). As can be seen from the figure, the order of the magnetic layers 30, 50 is reversed compared to the magnetoresistive device illustrated in FIG. 2. The free magnetic layer 30 of the device according to the present embodiment is positioned below a barrier layer 140, and the fixed magnetic layer 50 is positioned above the barrier layer 140 and adjacent to the digit line 10. Below these layers 30, 50 is a bit line 95 on top of a substrate (not shown). Optionally, the cell may furthermore comprise other layers depending on the application.

The device may for example be operated as a memory device. In that case, for a write cycle, a write current is applied through the write-digit line 10 and the bit line 95. As discussed above, the total write current of the magnetoresistive cell may be lowered because of the reverse order of the magnetic layers 30, 50 with respect to the prior art devices. The bit line current for each cell may then be lower than the write digit line current.

The invention of course requires a change in the process flow of the manufacturing process so as to change the order of the magnetic layers. However, there is no theoretical barrier to such a change.

The device according to the present invention may find application for example in MRAM memories as integrated circuits and any System-On-Chips where MRAM is embedded.

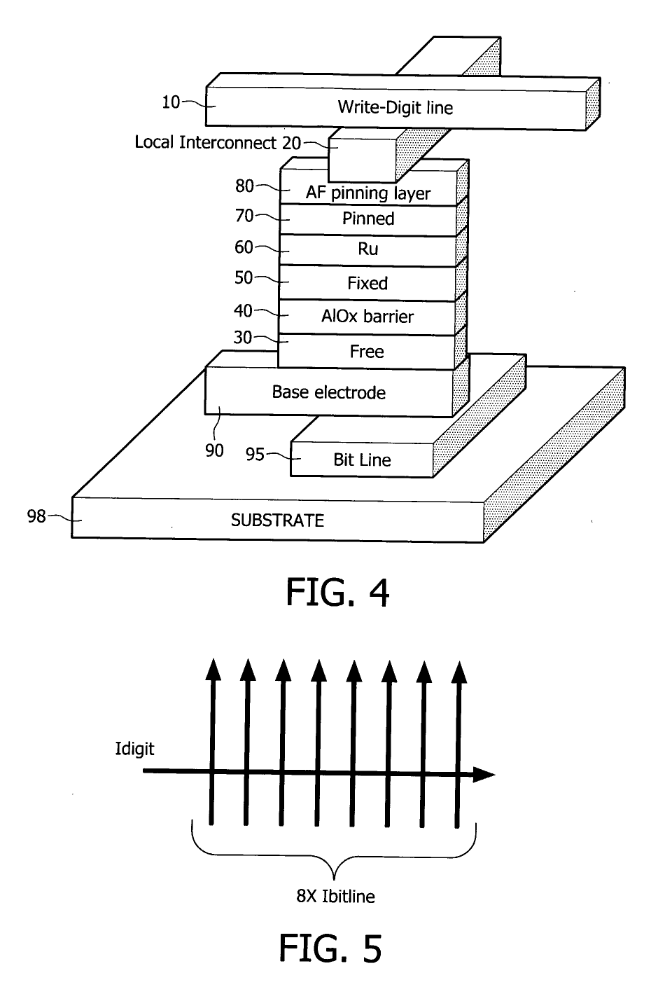

### FIG. 4, Second Embodiment

A second embodiment according to the present invention is illustrated in FIG. 4. In this embodiment, the magnetoresistive cell is an MTJ cell corresponding to the MTJ cell shown in FIG. 2. However, again the order of the magnetic layers 30, 50 in the cell is reversed relative to the current carrying lines and with respect to the prior art devices. In this embodiment, the bit line 95 is located on top of a substrate 98. On top of the bit line 95, a base electrode 90 is positioned which may be connected to ground through an isolation transistor as before (not shown). This base electrode is electrically isolated from the bit line. The magnetic layers of the cell are then positioned on top of the base electrode 90. The free magnetic layer 30 is positioned on top of the base electrode 90, followed by an AlOx tunnel barrier layer 40 separating the fixed and free magnetic layers 30, 50, which in turn is followed by the fixed magnetic layer 50. On top of these layers 30, 40, 50 a thin Ru layer 60, that with the fixed and pinned magnetic layer will form a structure with strong anti-parallel coupling, is positioned followed by an electrically isolated and perpendicularly running pinned layer 70 and an AF layer 80. A local interconnect line 20 parallel to the bit line 95 comes next, followed by the perpendicular running write-digit line 10. Other parts of the memory chip, such as for example other memory cells, addressing and timing circuitry, and read and write circuits are not shown in FIG. 4 for the sake of clarity. Likewise, the read and write operation of these devices may follow known practice and is not described here in more detail.

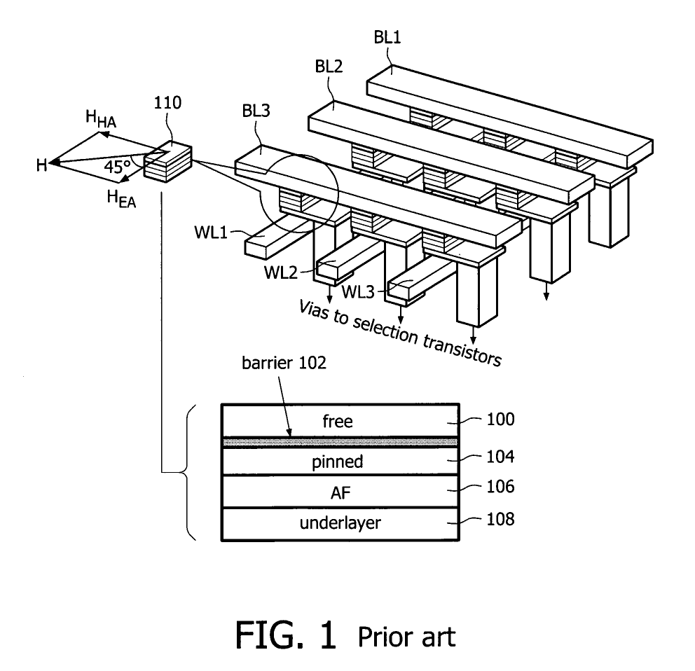

In the following, the total write current, required for the device according to the present invention, will be discussed. FIG. 5 shows schematically the write currents necessary for programming a byte of 8 bits in 8 cells. As can be seen, 8 times the bitline current I_{bitline} and 1 time the write-digit line current I_{digit} is required. To write a byte of data into the MRAM memory, 8 bits are required. To program one bit in a prior art device a current of around 12 mA may be required through the bit line 95 and a current of 6 mA may be required through the digit line 10. Even when the local interconnect 20 (FIG. 2) is omitted from the cell-architecture, as is the case in FIG. 1, the write-bit line current may still be larger than the digit line current (6 mA versus 5 mA, as shown in ‘A High Speed 128 kbit MRAM core for future universal memory applications’, A. Bette et. al. VLSI Circuits, 2003. Digest of Technical Papers. 2003 Symposium on , Jun. 12-14, 2003; Page(s): 217-220.). In a device according to present invention (FIG. 4) the write digit line current will be around 12 mA and the bitline current about 6 mA. Even omitting the local interconnect (FIG. 3) the digit line current is expected to be larger than the bit line current. Hence, there may still be a reduction in the total write current possible.

Some example values of currents will now be calculated to provide a comparison between the write currents required for the devices according to the present invention and the write current required for devices according to the prior art.

In the prior art example of FIG. 2, the maximum total write current for a byte would be 1×I_{digit}+8×I_{bitline} which gives 1×6 mA+8×12 mA=102 mA.

With the arrangement according to FIGS. 3 and 4, the bit line current is needed 8 times and the digit line current, which is higher than the bit line current, is needed only once. Hence, by reversing the order of the magnetic layers 30, 50 relative to the current carrying lines, i.e. the bit lines 95 and the digit lines 10 and redefining the function of the current carrying lines, as in FIGS. 3 and 4, writing a byte costs 8 times the lower current and only one time the high current. Hence, the total current for writing one byte will be 1*12 mA+8×6 mA=60 mA, which is much lower than the current required in case of the prior art device of FIG. 2.

As has been described above, a magnetoresistive memory device has cells, each having a free magnetic layer 30 and a fixed magnetic layer 50, and a bit line 95 for carrying a writing current. A digit line 10 common to a number of the cells, carries a digit write current. The magnetic layers 30, 50 are in between the bit lines 95 and digit lines 10, but in a reversal of the usual layout, the bit line 95 is closer to the free magnetic layer. This enables a reduction in total write current where the write current in the line nearer the magnetic layer will be less, as theoretically the current induced magnetic field is inverse proportional with the distance. Since there are more bit lines 95 than digit lines 10, the total of the bit currents and the digit current may be reduced. A reduced total write current may be useful in mobile battery powered applications in order to maximize battery life. Other variations are conceivable within the scope of the claims.

It is to be understood that although preferred embodiments, specific constructions and configurations, as well as materials, have been discussed herein for devices according to the present invention, various changes or modifications in form and detail may be made without departing from the scope and spirit of this invention.

1. A magnetoresistive device having a number of magnetoresistive cells logically organized in rows and columns, each cell comprising
a free magnetic layer and a fixed magnetic layer,
the device furthermore comprising a bit line for each column of magnetoresistive cell and digit lines, each digit line being common to a number of magnetoresistive cells in a row and being positioned in a direction perpendicular to the bit lines,
there being a first distance between a digit line and the fixed magnetic layer of a magnetoresistive cell and a second distance between said digit line and the free magnetic layer of the same magnetoresistive cell, the first distance being smaller than the second distance.

2. A device according to claim 1, wherein the magnetic layers are arranged adjacent to their respective bit line and adjacent to the digit line with the bit line closer to the free magnetic layer than the digit line to the fixed magnetic layer.

3. A device according to claim 1, wherein the device is a memory device for storing bits in the magnetoresistive cells and wherein the bit line and the digit line are arranged to carry writing currents.

4. A device according to claim 3, wherein the memory device is an MRAM device.

5. A device according to claim 1, wherein the free magnetic layer and the fixed magnetic layer are positioned in between the digit line and the bitline.

6. A device according to claim 1, the device furthermore comprising a local interconnect line parallel to and adjacent to each of the bit lines.

7. A device according to claim 1, wherein the magnetoresistive cells comprise Magnetic Tunnel Junction (MTJ) cells.

8. A device according to claim 7, wherein the MTJ cells furthermore comprise a pinned magnetic layer and an antiferromagnetic (AF) layer in between the digit line and the fixed magnetic layer.

9. A device according to claim 1, wherein the bit line is located in-between a substrate and a base electrode, said base electrode being positioned at a first side of the device and the digit lines being located at a second side of the device, the first and second side of the device being opposite to each other.

10. A device according to claim 1, wherein the digit line is coupled to eight or more of the magnetoresistive cells.

11. An integrated circuit comprising an embedded MRAM, the MRAM comprising one or more of the devices according to any of the preceding claims.

12. A method for manufacturing a magnetoresistive device comprising a number of magnetoresistive cells, each cell comprising a free magnetic layer and a fixed magnetic layer,
the device furthermore comprising a bit line for each column of magnetoresistive cells and digit lines, each digit line being common to a number of magnetoresistive cells in a row and being positioned in a direction perpendicular to the bit lines,
the method comprising:
forming a bit line onto a substrate,
forming a free magnetic layer on top of said bit line,
forming a barrier layer on top of said free magnetic layer,
forming a fixed magnetic layer on top of said barrier layer, and
forming a digit line on top of said fixed magnetic layer.

13. A method according to claim 12, wherein there is a first distance between a digit line and the fixed magnetic layer of a magnetoresistive cell and a second distance between the digit line and the free magnetic layer of the same magnetoresistive cell, the first distance being smaller than the second distance.

14. A method according to claim 12, the method furthermore comprising forming a pinned magnetic layer and an antiferromagnetic layer in between the fixed magnetic layer and the digit line.

15. A method for writing a group of bits to a group of cells of a magnetoresistive memory device, each cell comprising a free magnetic layer and a fixed magnetic layer,
the device furthermore comprising a bit line for each magnetoresistive cell and digit lines, each digit line being common to each of said group of cells and being positioned in a direction perpendicular to the bit lines,
the method comprising
applying a bit writing current to the bit lines of at least one cell, and
applying a digit write current to the digit line.

16. A method according to claim 15, there being a first distance between a digit line and the fixed magnetic layer of a magnetoresistive cell and a second distance between said digit line and the free magnetic layer of the same magnetoresistive cell, the first distance being smaller than the second distance.
